(19) United States
(12) Patent Application Publication
(10) Pub. No.: US 2026/0181999 A1
(43) Pub. Date: Jun. 25, 2026

(54) SEMICONDUCTOR DEVICE AND METHOD OF MANUFACTURING SEMICONDUCTOR DEVICE

(71) Applicant: INSTITUTE OF MICROELECTRONICS, CHINESE ACADEMY OF SCIENCES, Beijing (CN)

(72) Inventors: Jianfeng GAO, Beijing (CN); Junjie LI, Beijing (CN); Na ZHOU, Beijing (CN); Weibing LIU, Beijing (CN); Tao YANG, Beijing (CN); Junfeng LI, Beijing (CN); Jun LUO, Beijing (CN)

(21) Appl. No.: 18/834,258

(22) PCT Filed: Jun. 3, 2024
(86) PCT No.: PCT/CN2024/097020

§ 371 Date: Jul. 30, 2024

(30) Foreign Application Priority Data
Jun. 14, 2023 (CN) 202310707780.2

(51) Int. Cl. H10D 84/01; H10D 30/00

(52) U.S. Cl. CPC H10D 84/0151; H10D 30/502; H10D 84/013; H10D 84/0147

(57) ABSTRACT

The present disclosure relates to a field of semiconductor technology, in particular to a semiconductor device and a method of manufacturing a semiconductor device. The semiconductor device includes a substrate, a nanosheet channel, a metal gate, a source/drain region, and an insulating dielectric layer. The nanosheet channel is located above the substrate. The metal gate surrounds the nanosheet channel. The source/drain region is connected to the nanosheet channel. The insulating dielectric layer is located between the substrate and the source/drain region, and between the substrate and the nanosheet channel. The method includes forming a trench penetrating a source/drain by etching of silicon in the source/drain region, and filling the trench with an insulating dielectric material, so as to form a complete isolation between a bottom of a channel and a bottom of the source/drain.

### CROSS REFERENCE TO RELATED APPLICATION

This application is a Section 371 National Stage Application of International Application No. PCT/CN2024/097020, filed on Jun. 3, 2024, entitled “SEMICONDUCTOR DEVICE AND METHOD OF MANUFACTURING SEMICONDUCTOR DEVICE”, which claims priority to Chinese Patent Application No. 202310707780.2 filed on Jun. 14, 2023, which is incorporated herein by reference in its entirety.

### TECHNICAL FIELD

The present disclosure relates to a field of semiconductor technology, in particular to a semiconductor device and a method of manufacturing a semiconductor device.

### BACKGROUND

With the continuous miniaturization of feature sizes of transistors, traditional MOSFET devices have undergone a transformation from planar structures to three-dimensional structures, which improves performances of the devices while reducing the impact of short channel effects. At present, the research progress of GAA (gate-all-around) stacked nanosheet FET has attracted widespread attention from academia and industry. Constantly updated manufacturing processes and key processes, as well as optimized device structures, are popular research directions for new type of CMOS devices. GAA stacked nanosheet FET is considered to be the mainstream device after 3 nm nodes.

GAA stacked nanosheet FET is a new type of device which has a gate-all-around structure and a horizontal nanosheet (NS) serving as a conductive channel, developed on a basis of FinFET and Nanowire-FET. In terms of gate control, the gate-all-around structure has better gate control ability than the FinFET device structure, which may effectively suppress the short channel effect of the device. In terms of current driving, Nanosheet-GAAFET has a stack design with effective gate adjustable and vertical horizontal direction, which may significantly enhance the current driving performance of the device.

In a CMOS integration process of conventional stacked nanosheet GAA-FET, a silicon substrate (or well region) is generally required to be heavily doped with a type opposite to a type of source/drain doping of the device, so as to weaken or avoid the substrate parasitic channel and channel leakage between the source and the drain. However, the substrate parasitic channel (parasitic FinFET) causes characteristics of the GAA device to deteriorate, and causes the gate control to fail under the short channel. A bilateral heavily doped PN junction is formed between the heavily doped substrate and the source/drain region, which increases the reverse junction leakage of the source/drain region and increases an entire leakage current of the device.

### SUMMARY

In a first aspect, the present disclosure provides a semiconductor device, including a substrate, a nanosheet channel, a metal gate, a source/drain region and an insulating dielectric layer. The nanosheet channel is located above the substrate. The metal gate surrounds the nanosheet channel. The source/drain region is connected to the nanosheet channel. The insulating dielectric layer is located between the substrate and the source/drain region, and between the substrate and the nanosheet channel.

As this technical solution, preferably, the semiconductor device further includes an interlayer dielectric layer, a first conductive channel and a second conductive channel. The interlayer dielectric layer is located above the source/drain region. The first conductive channel and the second conductive channel are provided inside the interlayer dielectric layer. The first conductive channel is connected to the source/drain region. The second conductive channel is connected to the metal gate.

In a second aspect, the present disclosure further discloses a method of manufacturing the above-mentioned semiconductor device, which should also fall within the scope of protection of the present disclosure. The manufacturing method includes:
forming a trench penetrating a source/drain by etching of silicon in the source/drain region, and filling the trench with an insulating dielectric material, so as to form a complete isolation between a bottom of a channel and a bottom of the source/drain.

As this technical solution, preferably, the manufacturing method includes:
step S1: sequentially growing a sacrificial layer and a channel layer on a substrate, etching the channel layer, the sacrificial layer and a part of the substrate into a plurality of periodically distributed fins, and forming a shallow trench isolation region between two adjacent fins;
step S2: forming a dummy gate layer on an exposed surface of the fin;
step S3: depositing a first spacer dielectric on both sides of the dummy gate layer, etching the first spacer dielectric in a horizontal direction to form a first spacer; performing source/drain etching on the fin to form the source/drain region on both sides of the first spacer for manufacturing the source/drain; etching off an edge part of the sacrificial layer in a central direction of the source/drain region to form an embedded recess; depositing a second spacer dielectric, so that an entire surface is covered by the second spacer dielectric and the embedded recess is filled with the second spacer dielectric, so as to form a second spacer; and removing a part of the second spacer dielectric located in the horizontal direction by anisotropic etching;
step S4: performing source/drain etching on the fin through an etching process, penetrating the bottom of the channel through isotropic etching, and depositing the insulating dielectric material into the trench, so that the entire surface is covered by the insulating dielectric material, so as to form the insulating dielectric layer;
step S5: performing isotropic etching on the filled insulating dielectric layer, retaining a part of the insulating dielectric layer at the bottom; performing isotropic etching on the second spacer, and removing a part of the second spacer dielectric located in a vertical direction, so as to form an inner spacer; and
step S6: epitaxially growing the source/drain region on a surface of the insulating dielectric layer, and doping the source/drain region.

As this technical solution, preferably, in the step S1, a height of the fin is in a range of 10 nm to 400 nm, a width of the fin is in a range of 1 nm to 100 nm, and etching stops at the substrate or below the substrate.

As this technical solution, preferably, in the step S3, a material of each of the first spacer dielectric and the second spacer dielectric includes one or more of: silicon nitride, doped silicon oxide and doped silicon carbide.

As this technical solution, preferably, in the step S4, when performing source/drain etching, a depth to width ratio h/a of the trench is greater than 1.

As this technical solution, preferably, in the step S4, when filling the insulating dielectric material, a thickness b of a deposited thin film is greater than 0.5a.

As this technical solution, preferably, in the step S6, when doping the source/drain region, for a P-type FET, a material of the source/drain region is boron doped SiGe, and for an N-type FET, the material of the source/drain region is phosphorus doped silicon.

As this technical solution, preferably, the manufacturing method further includes:
step S7: depositing an interlayer dielectric on the source/drain region, and performing chemical mechanical polishing on the interlayer dielectric until the dummy gate layer is exposed;
step S8: etching and removing the dummy gate layer;
step S9: etching and removing the sacrificial layer, so as to release the channel layer to form the nanosheet channel;
step S10: depositing a high K metal gate to form the metal gate surrounding the nanosheet channel; and
step S11: further depositing the interlayer dielectric to form contact holes in contact with the source/drain region and the metal gate respectively, etching the contact holes, and depositing a silicon compound, so as to form a first conductive channel and a second conductive channel respectively.

### BRIEF DESCRIPTION OF THE DRAWINGS

In order to provide a clearer explanation of the technical solutions in the specific embodiments of the present disclosure or in the related art, the accompanying drawings required in the description of the specific embodiments or the related art will be briefly introduced below. Apparently, the accompanying drawings in the following description are some embodiments of the present disclosure. For those ordinary skilled in the art, other accompanying drawings may be obtained based on these drawings without creative labor.

FIG. 1 is a cross-sectional view along an X-X′ direction after growing a SiGe/Si superlattice stacked layer on a silicon substrate according to the present disclosure;

FIG. 2 is a cross-sectional view along an X-X′ direction after forming a superlattice stacked layer into a plurality of periodically distributed fins according to the present disclosure;

FIG. 3 is a cross-sectional view along an X-X′ direction after forming a shallow trench isolation region between two adjacent fins according to the present disclosure;

FIG. 4 is a cross-sectional view along an X-X′ direction after forming a dummy gate stacked layer on an exposed surface of a fin according to the present disclosure;

FIG. 5 is a cross-sectional view along a Y-Y′ direction after forming a dummy gate stacked layer on an exposed surface of a fin according to the present disclosure;

FIG. 6 is a cross-sectional view along a Y-Y′ direction after forming a dummy gate structure by patterning according to the present disclosure;

FIG. 7 is a cross-sectional view along a Y-Y′ direction after depositing a first spacer dielectric according to the present disclosure;

FIG. 8 is a cross-sectional view along a Y-Y′ direction after forming a first spacer by etching a first spacer dielectric according to the present disclosure;

FIG. 9 is a cross-sectional view along a Y-Y′ direction after etching an edge of a sacrificial layer according to the present disclosure;

FIG. 10 is a cross-sectional view along a Y-Y′ direction after depositing an inner spacer dielectric according to the present disclosure;

FIG. 11 is a cross-sectional view along a Y-Y′ direction after removing a part of an inner spacer dielectric located in a horizontal direction according to the present disclosure;

FIG. 12 is a schematic diagram of a three-dimensional structure after forming a channel according to the present disclosure;

FIG. 13 is a partial cross-sectional view along an X-X′ direction before forming a channel according to the present disclosure;

FIG. 14 is a cross-sectional view along a Y-Y′ direction after forming a channel according to the present disclosure;

FIG. 15 is a partial cross-sectional view along an X-X′ direction after forming a channel according to the present disclosure;

FIG. 16 is a cross-sectional view along an X-X′ direction after forming a channel according to the present disclosure;

FIG. 17 is a cross-sectional view along a Y-Y′ direction after depositing an insulating dielectric material according to the present disclosure;

FIG. 18 is a cross-sectional view along a Y-Y′ direction after isotropic etching a filled insulating dielectric layer according to the present disclosure;

FIG. 19 is a cross-sectional view along a Y-Y′ direction after forming an inner spacer according to the present disclosure;

FIG. 20 is a cross-sectional view along a Y-Y′ direction after epitaxially growing a source/drain region according to the present disclosure;

FIG. 21 is a cross-sectional view along a Y-Y′ direction after depositing an interlayer dielectric layer on a source/drain region according to the present disclosure;

FIG. 22 is a cross-sectional view along a Y-Y′ direction after etching off a dummy gate layer according to the present disclosure;

FIG. 23 is a cross-sectional view along an X-X′ direction after selectively etching a sacrificial layer in a superlattice stacked layer according to the present disclosure;

FIG. 24 is a cross-sectional view along an X-X′ direction after depositing a high K metal gate according to the present disclosure;

FIG. 25 is a cross-sectional view along an X-X′ direction after depositing an interlayer dielectric at a top according to the present disclosure.

### DESCRIPTION OF REFERENCE NUMERALS

1: substrate; 2: sacrificial layer; 3: channel layer; 4: hard mask layer; 5: shallow trench isolation region; 6: dummy gate layer; 7: first spacer; 8: second spacer; 9: trench; 10: insulating dielectric layer; 11: inner spacer; 12: source/drain region; 13: interlayer dielectric layer; 14: metal gate; 15: first conductive channel; 16: second conductive channel.

### DETAILED DESCRIPTION OF EMBODIMENTS

The technical solution of the present disclosure will be described clearly and completely below in conjunction with embodiments. Apparently, the described embodiments are some embodiments of the present disclosure, rather than all embodiments. Based on the embodiments of the present disclosure, all other embodiments obtained by those ordinary skilled in the art without creative labor, fall within the scope of protection of the present disclosure.

In the description of the present disclosure, it should be understood that orientations or position relationships indicated by the terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, etc. are based on the orientations or position relationships shown in the drawings, and are only for the convenience of describing the present disclosure and simplifying the description, rather than indicating or implying that the device or element referred to must have a specific orientation, or must be constructed and operated in a specific orientation, therefore it may not be understood as a limitation on the present disclosure.

In addition, the terms “first” and “second” are only used to description purpose and may not be understood as indicating or implying relative importance or implying the quantity of technical features indicated. Therefore, the features limited with “first” and “second” may explicitly or implicitly include one or more of the features. In the description of the present disclosure, “a plurality of” means two or more, unless otherwise clearly and specifically defined. In addition, the terms “mounted”, “connected”, and “connection” should be broadly understood. For example, it may be a fixed connection, a detachable connection, or an integrated connection; it may be a mechanical connection or an electrical connection; it may be directly connected, or indirectly connected through an intermediate medium; and it may be an internal connection between two elements. For those ordinary skilled in the art, specific meanings of the terms described above in the present disclosure may be understood based on specific circumstances.

The purpose of the present disclosure is to provide a semiconductor device and a method of manufacturing a semiconductor device. Through the integrated process, the insulating dielectric isolation is formed at the bottom of the source/drain region and the bottom of the channel, thereby fundamentally eliminating the substrate parasitic channel and channel leakage between the source and the drain.

The present disclosure proposes a new type of method of manufacturing a semiconductor device, which has a simple process and is compatible with the existing GAA process. The method is mainly used to form an insulating dielectric isolation at the bottom of the source/drain region and the bottom of the channel through an integrated process, so as to eliminate the substrate parasitic channel and channel leakage between the source and the drain.

This embodiment provides a method of manufacturing a semiconductor device, including steps S1 to S11.

In step S1, a sacrificial layer 2 and a channel layer 3 are sequentially grown on a substrate 1; the channel layer 3, the sacrificial layer 2 and a part of the substrate 1 are etched into a plurality of periodically distributed fins; and a shallow trench isolation region 5 is formed between two adjacent fins.

In step S2, a dummy gate layer 6 is formed on an exposed surface of the fin.

In step S3, a first spacer dielectric is deposited on both sides of the dummy gate layer 6, and the first spacer dielectric in a horizontal direction is etched, to form a first spacer 7; a source/drain region 12 for manufacturing a source/drain is formed on both sides of the first spacer 7 by performing source/drain etching on the fin; in a central direction of the source/drain region 12, an edge part of the sacrificial layer 2 is etched off to form an embedded recess; a second spacer dielectric is deposited, so that the second spacer dielectric covers an entire surface and fills the embedded recess, so as to form a second spacer 8; and a part of the second spacer dielectric located in the horizontal direction is removed by anisotropic etching.

In step S4, source/drain etching is performed on the fin through an etching process, the bottom of the channel is penetrated through isotropic etching, and the insulating dielectric material is deposited into the trench 9, so that the entire surface is covered by the insulating dielectric material, so as to form an insulating dielectric layer 10.

In step S5, isotropic etching is performed on the filled insulating dielectric layer 10, a part of the insulating dielectric layer 10 at the bottom is retained; isotropic etching is performed on the second spacer 8, and a part of the second spacer dielectric 8 located in a vertical direction is removed, so as to form an inner spacer 11.

In step S6, the source/drain region 12 is epitaxially grown on a surface of the insulating dielectric layer 10, and the source/drain region 12 is doped.

In step S7, an interlayer dielectric is deposited on the source/drain region 12, and chemical mechanical polishing is performed on the interlayer dielectric until the dummy gate layer 6 is exposed.

In step S8, the dummy gate layer 6 is etched and removed.

In step S9, the sacrificial layer 2 is etched and removed, so as to release the channel layer 3 to form the nanosheet channel.

In step S10, a high K metal gate 14 is deposited to form the metal gate 14 surrounding the nanosheet channel.

In step S11, the interlayer dielectric is further deposited to form contact holes in contact with the source/drain region 12 and the metal gate 14 respectively, the contact holes are etched, and a silicon compound is deposited, so as to form a first conductive channel 15 and a second conductive channel 16 respectively.

The manufacturing method will be described in more detail below.

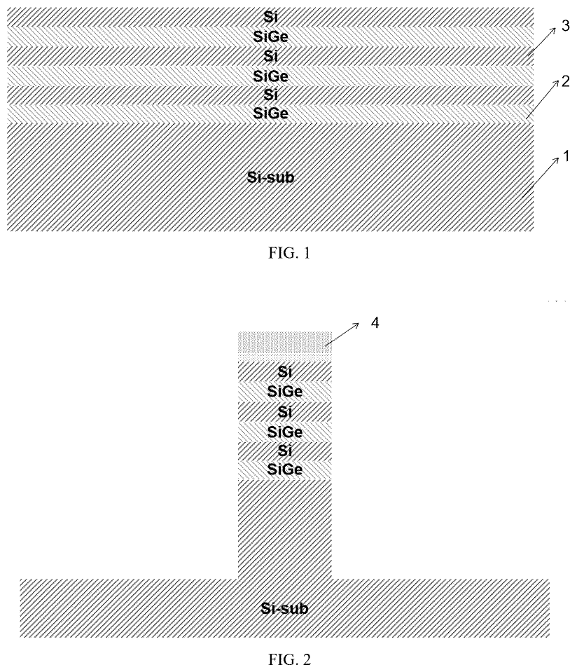

In the step S1, as shown in FIG. 1, the sacrificial layer 2 and the channel layer 3 are sequentially grown on the substrate 1 by epitaxy. The substrate 1 is a silicon substrate 1 in general. The sacrificial layer 2 is generally made of SiGe. The channel layer 3 is generally made of Si. The sacrificial layer 2 and the channel layer 3 are superlattice structures. The Si layer determines the number of nanowires in the subsequent process. The number of Si layers is greater than or equal to 1, and a thickness of each layer is less than 30 nm. The final produced thickness directly determines a height and an electrical performance of the nanosheet channel.

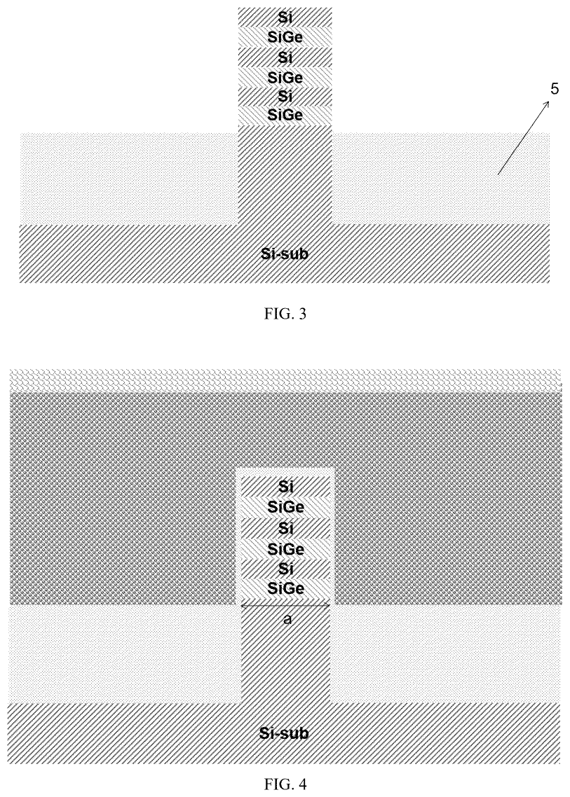

On the basis of the above, as shown in FIG. 2, further, the sacrificial layer 2 and the channel layer 3 are formed into a plurality of periodically distributed fins. Specifically, the hard mask layer 4 is deposited above the uppermost channel layer 3, and after patterning, the epitaxially grown superlattice stacked layer is formed into the plurality of periodically distributed fins through an etching process. A height of each of the fins is in a range of 10 nm to 400 nm, and a width of each of the fins is in a range of 1 nm to 100 nm. Etching stops at the substrate 1 or below the substrate 1.

On the basis of the above, as shown in FIG. 3, the shallow trench isolation (STI) region 5 is formed between two adjacent fins. Specifically, an insulating dielectric material is deposited and planarized firstly. After exposing the hard mask layer 4, the hard mask layer 4 is removed through wet or dry etching. Then, the insulating dielectric material is selectively etched back to expose a three-dimensional fin structure, so as to form the shallow trench isolation region 5 between adjacent fins. An upper surface of the shallow trench isolation region 5 may be generally flush with an interface between the superlattice stacked layer structure in the fin and the substrate 1 of monocrystalline silicon, and may also be higher or lower than a horizontal line of the interface.

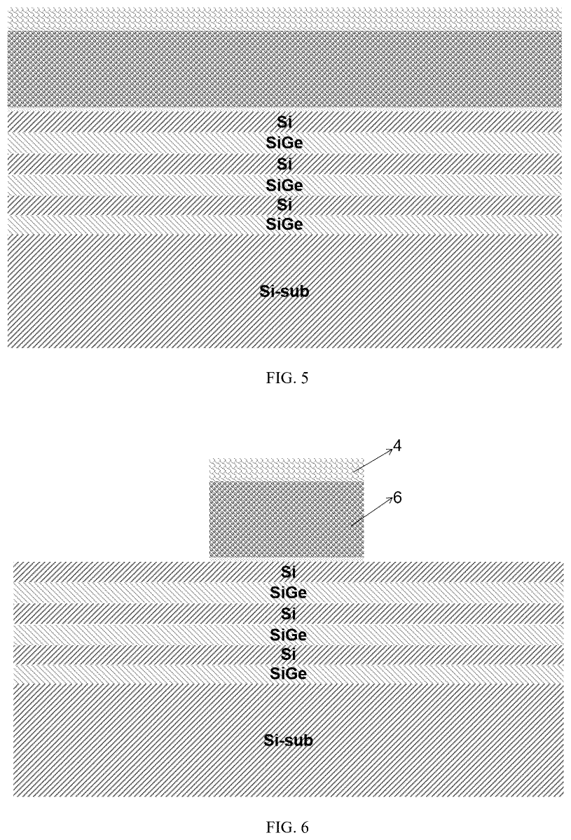

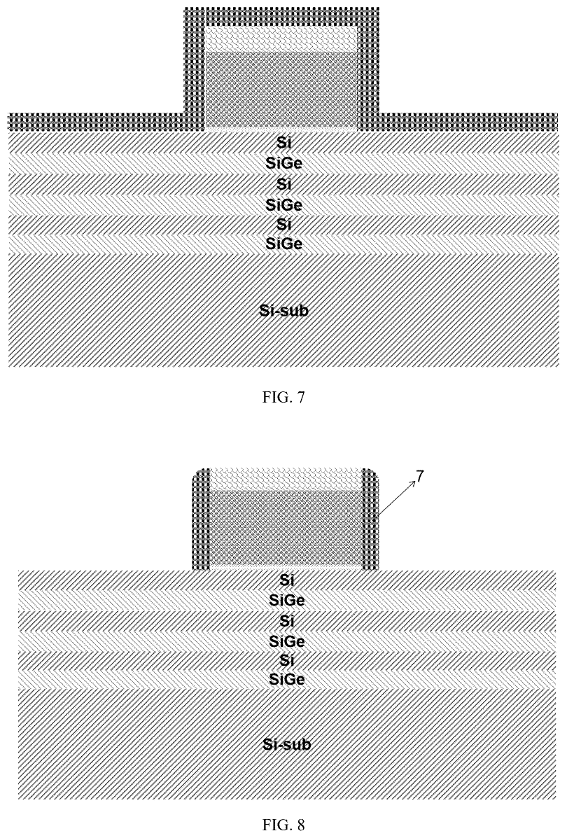

In the step S2, as shown in FIG. 4 to FIG. 5, the dummy gate layer 6 is formed on the exposed surface of the fin. Specifically, an oxide layer and polycrystalline silicon (or amorphous silicon) are sequentially deposited above the shallow trench isolation region 5 and CMP (chemical mechanical polishing) is performed, and then a dummy gate hard mask layer is deposited. Next, as shown in FIG. 6, a dummy gate across the fins is formed through photolithography and etching patterning processes. After etching, the hard mask layer above the dummy gate is retained.

A material of the dummy gate hard mask layer may be oxide, carbide, organic compound, etc.

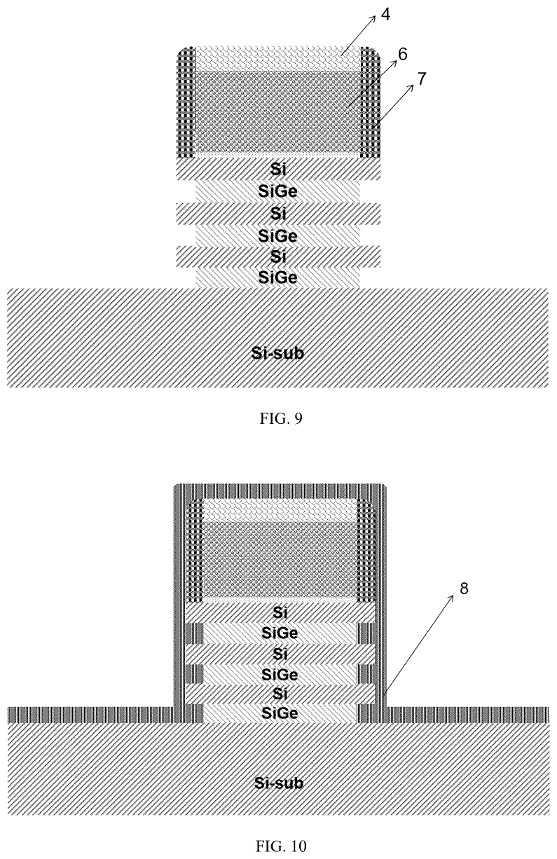

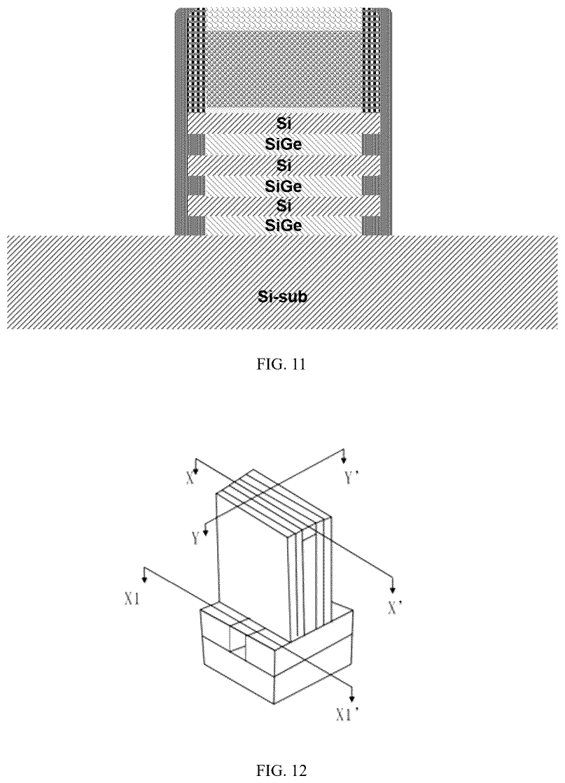

In the step S3, as shown in FIG. 7 to FIG. 8, the first spacer dielectric is deposited on both sides of the dummy gate layer 6, the spacer dielectric in the horizontal direction is etched off, and only the dielectric on the sidewall of the dummy gate and the dielectric on the sidewall of the dummy gate hard mask layer are retained, so as to form the first spacer 7. Then, on a basis of FIG. 8 and with reference to FIG. 9, by using the dummy gate hard mask layer 4 and the first spacer 7 as a mask, source/drain etching is performed on the fin through an etching process. The source/drain region 12 for manufacturing the source/drain is formed on both sides of the first spacer 7, and an edge part of the sacrificial layer 2 is etched off in the central direction of the source/drain region 12, so as to form an embedded recess. Furthermore, on a basis of FIG. 9 and with reference to FIG. 10, the second spacer dielectric is deposited, so that the entire surface is covered by the second spacer dielectric and the embedded recess is filled with the second spacer dielectric, so as to form the second spacer 8. Finally, on a basis of FIG. 10 and with reference to FIG. 11, a part of the second spacer dielectric located in the horizontal direction is removed by anisotropic etching.

The material of the first spacer dielectric and the material of the second spacer dielectric may be dielectrics such as silicon nitride, doped silicon oxide, and doped silicon carbide. During etching, the sacrificial layer 2 and the channel layer 3 have a large etching selectivity ratio, thus ensuring the integrity of the channel layer 3.

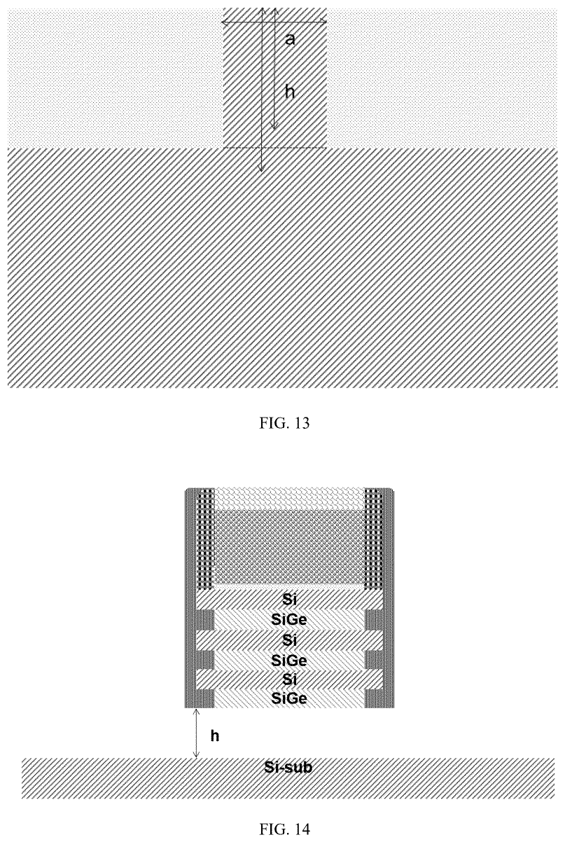

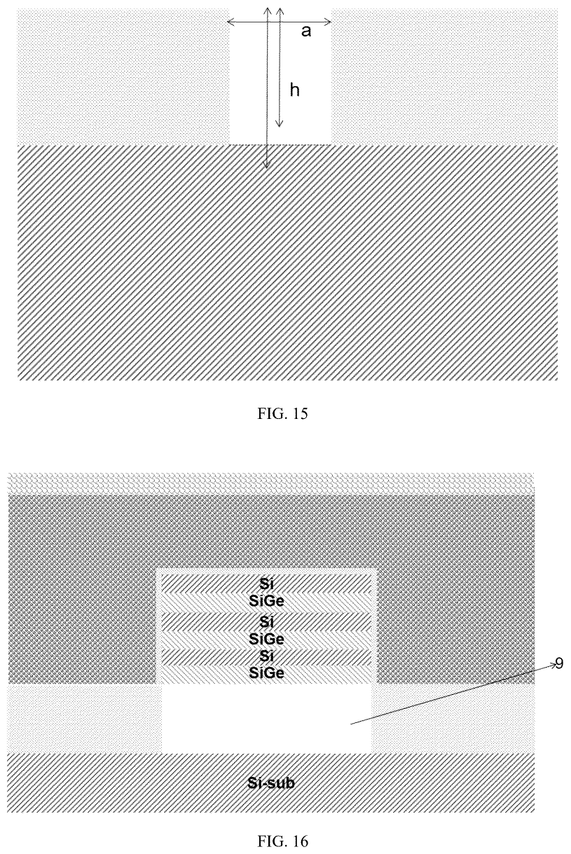

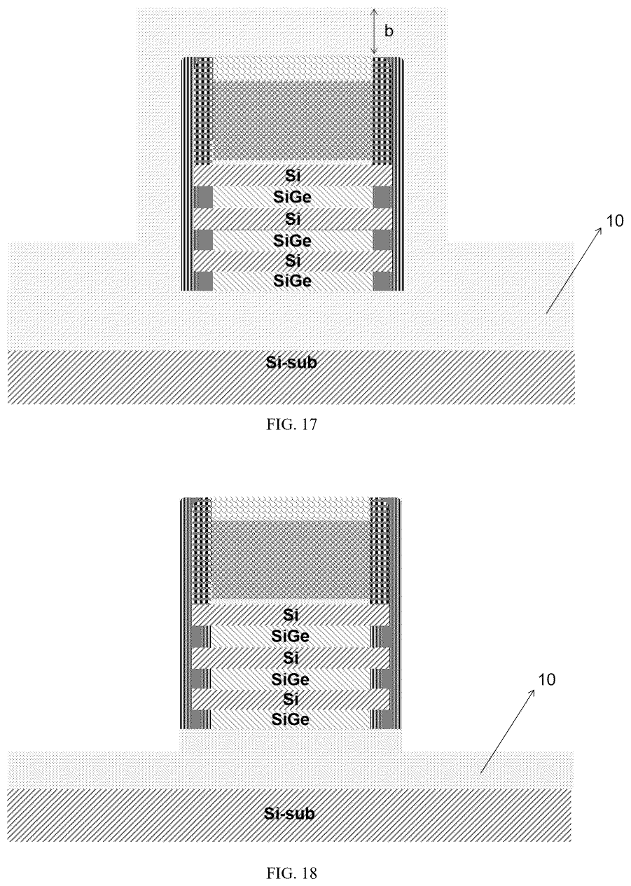

In the step S4, as shown in FIG. 12 to FIG. 16, by using the dummy gate hard mask layer 6 and the first spacer 7 as a mask, source/drain etching is performed on the fin through an etching process, and the bottom of the channel is penetrated through isotropic etching. An etching depth may be slightly higher or lower than the bottom of the STI, ensuring that a depth (h) to width (a) ratio h/a of the trench 9 formed after the source/drain etching is greater than 1. Then, with reference to FIG. 17, the channel is filled with the insulating dielectric material using deposition methods with good shape preservation such as atomic layer deposition or CVD, and the entire surface is covered by the insulating dielectric material, so as to form the insulating dielectric layer 10. Specifically, a thickness b of the deposited thin film is greater than 0.5a, so as to ensure the channel of the source/drain to be completely filled.

The deposited insulating dielectric material may be SiO₂ and a low dielectric material, which may be the same as or different from the material of the shallow trench isolation region 5.

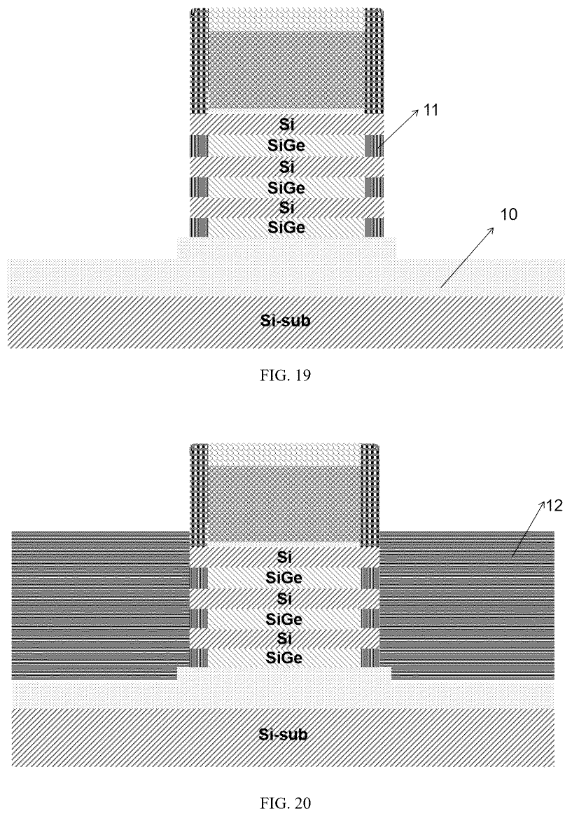

In the step S5, as shown in FIG. 18, isotropic etching is performed on the filled insulating dielectric layer 10, and a part of the insulating dielectric layer 10 located at the bottom is retained. Then, with reference to FIG. 19, isotropic etching is performed on the second spacer 8, and a part of the second spacer located in the vertical direction is removed, so as to form the inner spacer 11.

In the step S6, with reference to FIG. 20, the source/drain region 12 is epitaxially grown by using methods such as metal organic chemical vapor deposition, molecular beam epitaxy, liquid phase epitaxy, vapor phase epitaxy, selective epitaxial growth, or a combination of the aforementioned methods. At the same time, the source/drain region 12 is doped. For a P-type FET, the material of the source/drain region 12 is boron doped SiGe (SiGe:B). For an N-type FET, the material of the source/drain region 12 is phosphorus doped silicon (Si:P).

From the above manufacturing method, it may be seen that the inner spacer 11 of the present disclosure is formed through two etching processes. The first etching process involves anisotropic etching to remove the spacer thin film of the source/drain region 12 in the horizontal direction, and the second etching process involves isotropic etching to form the inner spacer 11. Between the two etching processes for the inner spacer 11 in the present disclosure, the trench 9 penetrating the source/drain is formed by etching of silicon in the source/drain region 12. Then, the trench 9 is filled with the insulating dielectric thin film with good shape preservation, so as to form a complete isolation between the bottom of the channel and the bottom of the source/drain. Therefore, in the present disclosure, an insulating dielectric isolation is formed at the bottom of the source/drain region 12 and the bottom of the channel through an integrated process, thereby fundamentally eliminating the substrate parasitic channel and channel leakage between the source and the drain.

In the step S7, after forming the source/drain region 12, as shown in FIG. 21, the interlayer dielectric is deposited on the source/drain region 12, and CMP is performed on the interlayer dielectric, so that the interlayer dielectric is planarized. The hard mask layer 4 is removed, so as to expose the dummy gate layer 6.

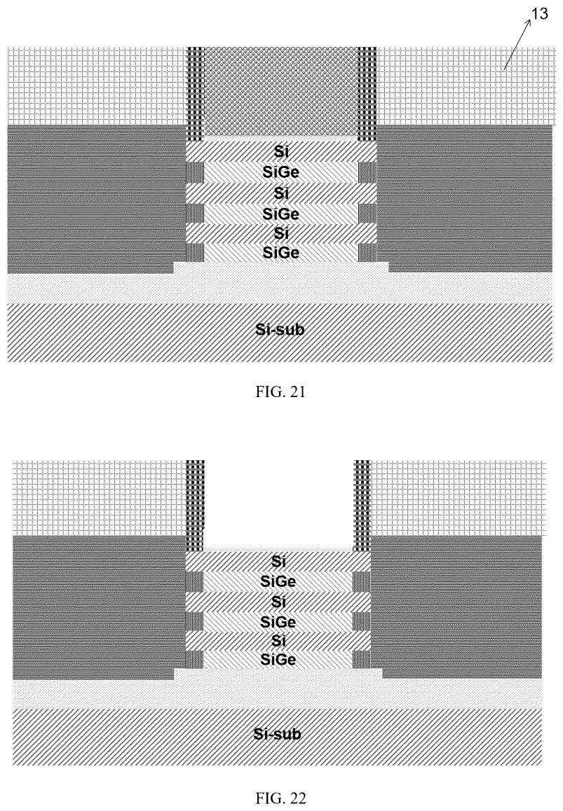

In the step S8, on the basis of the above, further, as shown in FIG. 22, the dummy gate layer 6 formed by the aforementioned polycrystalline or amorphous silicon is etched off through selective etching or corrosion process.

In the step S9, on the basis of the above, further, as shown in FIG. 23, the sacrificial layer 2 in the superlattice stacked layer is selectively etched, so as to release the nanosheet channel.

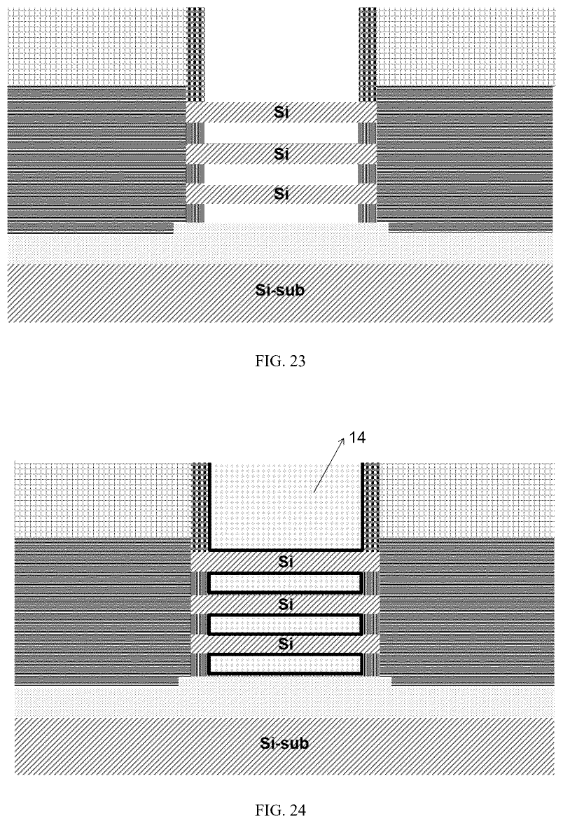

In the step S10, on the basis of the above, further, as shown in FIG. 24, the high K metal gate is deposited and CMP is performed, so as to form the NMOS metal gate and the PMOS metal gate.

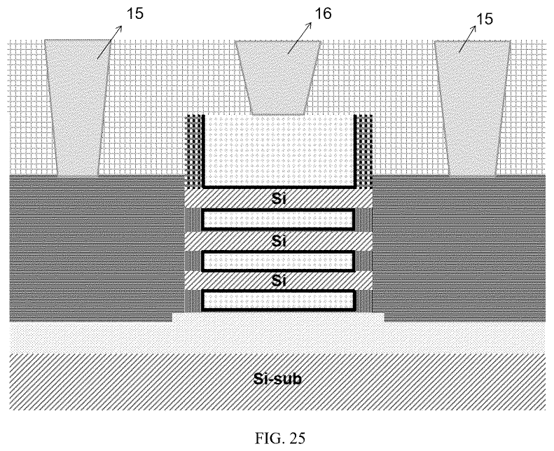

In the step S11, on the basis of the above, further, as shown in FIG. 25, the interlayer dielectric is deposited at the top, and dielectric CMP is performed. Then, contact hole photolithography and etching are performed, and silicide is deposited, so as to form a contact hole in contact with the source/drain region 12 and a contact hole in contact with the metal gate 14, and form a conductive channel in each of the contact holes.

In another aspect, another embodiment of the present disclosure further provides a semiconductor device, including: a substrate 1, a nanosheet channel, a metal gate 14, a source/drain region 12, an insulating dielectric layer 10, an interlayer dielectric layer 13, a first conductive channel 15 and a second conductive channel 16. The nanosheet channel is located above the substrate 1. The metal gate 14 surrounds the nanosheet channel. The source/drain region 12 is connected to the nanosheet channel. The insulating dielectric layer 10 is located between the substrate 1 and the source/drain region 12, and between the substrate 1 and the nanosheet channel. The interlayer dielectric layer 13 is located above the source/drain region 12. The first conductive channel 15 and the second conductive channel 16 are provided inside the interlayer dielectric layer 13. The first conductive channel 15 is connected to the source/drain region 12. The second conductive channel 16 is connected to the metal gate 14.

The semiconductor device in the above embodiment is formed using the aforementioned method embodiments, and the materials and characteristics of various parts of the semiconductor device may refer to the aforementioned method embodiments, which will not be repeated here.

The semiconductor device and the method of manufacturing the semiconductor device of the present disclosure have at least following technical effects.
1. The semiconductor device of the present disclosure includes a substrate, a nanosheet channel, a metal gate, a source/drain region and an insulating dielectric layer. The insulating dielectric layer is located between the substrate and the source/drain region, and between the substrate and the nanosheet channel. Compared with the related art, the substrate parasitic channel and channel leakage between the source and the drain may be fundamentally eliminated by providing the insulating dielectric layer.
2. In a process of manufacturing the semiconductor device of the present disclosure, the trench penetrating the source/drain is formed by etching of silicon in the source/drain region, and the trench is filled with the insulating dielectric material, so as to form the complete isolation between the bottom of the channel and the bottom of the source/drain. Compared with processes such as heavily doping of an active region, the process costs of the method of the present disclosure may be greatly reduced.

In the above description, there is no detailed explanation of the technical details such as patterning and etching of each layer. However, those skilled in the art should understand that layers, regions, etc. of the desired shapes may be formed through various technical means. In addition, in order to form the same structure, those skilled in the art may also design methods that are not completely the same as the methods described above. Furthermore, although various embodiments have been described separately above, it does not mean that the measures in various embodiments may not be advantageously used in combination.

Finally, it should be noted that the above embodiments are only used to illustrate the technical solution of the present disclosure, rather than to limit it. Although the present disclosure has been described in detail with reference to the aforementioned embodiments, those skilled in the art should understand that they may still modify the technical solutions described in the aforementioned embodiments, or replace some or all of the technical features therein with equivalents. However, these modifications or replacements do not cause the essence of the corresponding technical solutions to deviate from the scope of the technical solutions of the various embodiments of the present disclosure.

1-10. (canceled)

11: A semiconductor device, comprising: a substrate, a nanosheet channel, a metal gate, a source/drain region and an insulating dielectric layer,
wherein the nanosheet channel is located above the substrate, the metal gate surrounds the nanosheet channel, the source/drain region is connected to the nanosheet channel, and the insulating dielectric layer is located between the substrate and the source/drain region, and between the substrate and the nanosheet channel.

12: The semiconductor device of claim 11, further comprising: an interlayer dielectric layer, a first conductive channel and a second conductive channel,
wherein the interlayer dielectric layer is located above the source/drain region, the first conductive channel and the second conductive channel are provided inside the interlayer dielectric layer, the first conductive channel is connected to the source/drain region, and the second conductive channel is connected to the metal gate.

13: A method of manufacturing the semiconductor device of claim 11, comprising:
forming a trench penetrating a source/drain by etching of silicon in the source/drain region, and
filling the trench with an insulating dielectric material, so as to form a complete isolation between a bottom of a channel and a bottom of the source/drain.

14: The manufacturing method of claim 13, comprising:
step S1: sequentially growing a sacrificial layer and a channel layer on the substrate, etching the channel layer, the sacrificial layer and a part of the substrate into a plurality of periodically distributed fins, and forming a shallow trench isolation region between two adjacent fins;
step S2: forming a dummy gate layer on an exposed surface of the fin;
step S3: depositing a first spacer dielectric on both sides of the dummy gate layer, and etching the first spacer dielectric in a horizontal direction to form a first spacer;
performing source/drain etching on the fin to form the source/drain region on both sides of the first spacer for manufacturing the source/drain; etching off an edge part of the sacrificial layer in a central direction of the source/drain region to form an embedded recess; depositing a second spacer dielectric, so that an entire surface is covered by the second spacer dielectric and the embedded recess is filled with the second spacer dielectric, so as to form a second spacer; and removing a part of the second spacer dielectric located in the horizontal direction by anisotropic etching;
step S4: performing source/drain etching on the fin through an etching process, penetrating the bottom of the channel through isotropic etching, and depositing the insulating dielectric material into the trench, so that the entire surface is covered by the insulating dielectric material, so as to form the insulating dielectric layer;
step S5: performing isotropic etching on the filled insulating dielectric layer, retaining a part of the insulating dielectric layer at the bottom; performing isotropic etching on the second spacer, and removing a part of the second spacer dielectric located in a vertical direction, so as to form an inner spacer; and
step S6: epitaxially growing the source/drain region on a surface of the insulating dielectric layer, and doping the source/drain region.

15: The manufacturing method of claim 14, wherein in the step S1, a height of the fin is in a range of 10 nm to 400 nm, a width of the fin is in a range of 1 nm to 100 nm, and etching stops at the substrate or below the substrate.

16: The manufacturing method of claim 14, wherein in the step S3, a material of each of the first spacer dielectric and the second spacer dielectric comprises one or more of: silicon nitride, doped silicon oxide and doped silicon carbide.

17: The manufacturing method of claim 14, wherein in the step S4, when performing source/drain etching, a depth to width ratio h/a of the trench is greater than 1.

18: The manufacturing method of claim 14, wherein in the step S4, when filling the insulating dielectric material, a thickness b of a deposited thin film is greater than 0.5a.

19: The manufacturing method of claim 14, wherein in the step S6, when doping the source/drain region, for a P-type FET, a material of the source/drain region is boron doped SiGe, and for an N-type FET, the material of the source/drain region is phosphorus doped silicon.

20: The manufacturing method of claim 14, further comprising:
step S7: depositing an interlayer dielectric on the source/drain region, and performing chemical mechanical polishing on the interlayer dielectric until the dummy gate layer is exposed;
step S8: etching and removing the dummy gate layer;
step S9: etching and removing the sacrificial layer, so as to release the channel layer to form the nanosheet channel;
step S10: depositing a high K metal gate to form the metal gate surrounding the nanosheet channel; and
step S11: further depositing the interlayer dielectric to form contact holes in contact with the source/drain region and the metal gate respectively, etching the contact holes, and depositing a silicon compound, so as to form a first conductive channel and a second conductive channel respectively.
